(19) United States
(12) Patent Application Publication
(10) Pub. No.: US 2024/0266320 A1
(43) Pub. Date: Aug. 8, 2024

(54) METHOD OF INTERCONNECTING SEMICONDUCTOR DEVICES AND ASSEMBLY OF INTERCONNECTED SEMICONDUCTOR DEVICES

(71) Applicant: Yibu Semiconductor Co., Ltd., Shanghai (CN)

(72) Inventor: Yifan Guo, Shanghai (CN)

(73) Assignee: Yibu Semiconductor Co., Ltd., Shanghai (CN)

(21) Appl. No.: 18/434,566

(22) Filed: Feb. 6, 2024

(30) Foreign Application Priority Data
Feb. 6, 2023 (CN) 202310100338.3

(51) Int. Cl. H01L 23/00

(52) U.S. Cl. CPC H01L 24/83; H01L 24/05; H01L 24/27; H01L 24/29; H01L 24/32; H01L 2224/05647; H01L 2224/2745; H01L 2224/27452; H01L 2224/29028; H01L 2224/29118; H01L 2224/29124; H01L 2224/29139; H01L 2224/29147; H01L 2224/2916; H01L 2224/29186; H01L 2224/29193; H01L 2224/29194; H01L 2224/32145; H01L 2224/32505; H01L 2224/83201; H01L 2224/838; H01L 2924/01035; H01L 2924/01053; H01L 2924/05381; H01L 2924/0541; H01L 2924/0542; H01L 2924/0543; H01L 2924/0544; H01L 2924/0581; H01L 2924/0582; H01L 2924/0583

(57) ABSTRACT

The present disclosure relates to a method of interconnecting semiconductor devices and an assembly of interconnected semiconductor devices. The method comprises forming a metal layer on a first connection surface of the first semiconductor device, and forming an oxidant layer on a second connection surface of the second semiconductor device, the first connection surface including first coupling pads, the second connection surface including the second coupling pads. The method further comprises aligning the first connecting pads and respective ones of the second connecting pads to each other, pressing together the metal layer and the oxidant layer, and reacting the metal layer with the oxidant layer under target condition to form a bonding layer. The bonding layer first regions, second regions, and third regions that are conductive regions, and a fourth region that is a nonconductive adhesive region. The method of interconnecting semiconductor devices allows alignment errors, improves yield, and reduces cost.

### CROSS REFERENCE TO RELATED APPLICATION

The present application claims the benefit of priority under the Paris Convention to Chinese Patent Application No. 20/231,0100338.3A, filed on Feb. 6, 2023, which is incorporated herein by reference in its entirety.

### TECHNICAL FIELD

The present disclosure relates to the field of semiconductor technologies, and in particular, to a method of interconnecting semiconductor devices and an interconnected semiconductor device assembly.

### BACKGROUND

Recent artificial intelligence applications place higher demands on high-speed computing, and since Moore's law is already approaching a limit, the improvement of computing power is more dependent on the multi-chip system integration technology, and high-density interconnection is the key to the multi-chip system integration technology.

Currently, methods of interconnecting semiconductor devices capable of achieving maximum density (or minimum pitch) in the industry is Hybrid Bonding (HB), which is used to implement Input or Output (I/O) interconnection between two wafers (or two chips), where the interconnection density can reach 1 micron pitch. Due to the extremely small pitch, the alignment requirements between two wafers (or two chips) during fabrication are extremely high, which not only causes a sharp rise in the price of the fabrication equipment, but also causes many difficulties in the fabrication process, such as yield loss due to inaccurate alignment, too much time required for accurate alignment, etc. In practice, even when high-precision equipment is used, it is difficult to avoid the situation that two wafers (or two chips) are misaligned with each other in the coupling process, and the I/O cannot be accurately docked, causing open circuit failure, thereby seriously affecting the product yield and leading to cost increase. Even if accurate abutment between the coupling pads is possible during the coupling process, failure is often caused by insufficient adhesion of the two abutting surfaces.

### SUMMARY

To improve and solve the above technical problems, a method of interconnecting semiconductor devices and an assembly of interconnected semiconductor devices are provided according to some embodiments.

In some embodiments, a method of interconnecting semiconductor devices comprises forming a metal layer on a first connection surface of a first semiconductor device, the first connection surface having first coupling pads, and forming an oxidant layer on a second connection surface of a second semiconductor device, the second connection surface having second coupling pads. The method further comprises aligning the first coupling pads with respective ones of the second coupling pads, whereby the first coupling pads respectively and at least partially overlap with the second coupling pads, pressing together the metal layer and the oxidant layer, and reacting the metal layer and the oxidant layer under target conditions to form a bonding layer between the first semiconductor device and the second semiconductor device.

In some embodiments, the bonding layer includes conductive regions and non-conductive adhesive regions. The conductive regions include first regions, second regions and third regions. Each of the first regions overlaps with a first coupling pad and a corresponding second coupling pad, each of the second region overlaps with a first coupling pad but not with any of the second coupling pads, and each of the third regions overlaps with a second coupling pad but not with any of the first coupling pads. The non-conductive adhesive regions correspond to areas not overlapping with any of the first coupling pads and the second coupling pads.

In some embodiments, the method further comprises, prior to aligning the first coupling pads with respective ones of the second coupling pads and pressing together the metal layer and the oxidant layer, removing portions of the oxidant layer in regions corresponding to the second coupling pads to expose the second coupling pads.

In some embodiments, the method further comprises polishing the first connection surface before forming the metal layer thereon, and/or polishing the second connection surface before forming the oxidant layer thereon.

In some embodiments, at least one of the first semiconductor device and the second semiconductor device is a wafer or a die.

In some embodiments, forming a metal layer on the first connection surface of the first semiconductor device comprises sputtering a target metal on the first connection surface to form the metal layer.

In some embodiments, the target metal comprises at least one of aluminum, copper, zinc, tin, nickel, iron, and silver.

In some embodiments, forming an oxidant layer on the second connection surface of the second semiconductor device comprises depositing a target oxidizing agent on the second connection surface to form the oxidant layer.

In some embodiments, the target oxidizing agent comprises at least one of hydrogen peroxide, potassium permanganate, potassium perchlorate, iodine and bromine.

In some embodiments, the target conditions include conditions related to at least one of pressurizing, heating, and providing a target gas.

In some embodiments, the target gas comprises one of oxygen, chlorine and fluorine.

In another aspect, the present disclosure also provides an assembly of interconnected semiconductor devices or a semiconductor device assembly. The semiconductor device assembly comprises: a first semiconductor device including first coupling pads; a second semiconductor device including second coupling pads, wherein the first coupling pads corresponds to, at least partially overlap with, and are connected to, respective ones of the second coupling pads; and a bonding layer between the first semiconductor device and the second semiconductor device.

In some embodiments, the bonding layer includes conductive regions and non-conductive adhesive regions, the conductive regions including first regions, second regions and third regions, each of the first regions overlapping with a first coupling pad and a corresponding second coupling pad and thus connecting the first coupling pad to the corresponding second coupling pad, each of the second region overlapping with a first coupling pad but not with any of the second coupling pads, each of the third regions overlapping with a second coupling pad but not with any of the first coupling pads, and the non-conductive adhesive regions corresponding to areas not overlapping with any of the first coupling pads and the second coupling pads.

Compared with the prior art, the technical schemes provided by the disclosure have various advantages. In the case of misalignment or imprecise alignment between the first coupling pads and the corresponding second coupling pads, the use of the second regions and the third regions increases the effective conductive area between the first coupling pads and the corresponding second coupling pads, thereby reducing the probability of disconnection between the corresponding coupling pads and thus improving the reliability of the interconnections. Meanwhile, the non-conductive adhesive regions provide reliable bonding in the corresponding areas for the first connection surface and the second connection surface, so that the bonding effect is enhanced, reliable bonding of the first connection surface and the second connection surface is realized, and interconnection reliability between the semiconductor devices is further improved. Thus, when the method of interconnecting semiconductor devices according to some embodiments is used for mass production, a certain alignment error can be allowed between two interconnected semiconductor devices, so that fault tolerance is improved, circuit breaking failure is reduced, yield is enhanced, and cost is reduced.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to more clearly illustrate the embodiments of the present disclosure or the solutions in the prior art, the drawings that are required for the description of the embodiments or the prior art will be briefly described below, and it will be obvious to those skilled in the art that other drawings can be obtained from these drawings without inventive effort.

FIG. 1 is a schematic flow chart of a method of interconnecting semiconductor devices according to an embodiment of the disclosure.

FIG. 2 is a schematic structural diagram corresponding to each step in the method of interconnecting semiconductor devices of the semiconductor device shown in FIG. 1.

FIG. 3 is a cross-sectional view of A-A in FIG. 2.

FIG. 4 is a flowchart illustrating another method for interconnecting semiconductor devices according to an embodiment of the present disclosure.

FIG. 5 is a schematic structural diagram corresponding to each step in the method of interconnecting semiconductor devices of the semiconductor device shown in FIG. 4.

FIG. 6 is a cross-sectional view of B-B in FIG. 5.

FIG. 7 is a flowchart illustrating another method for interconnecting semiconductor devices according to an embodiment of the present disclosure.

FIG. 8 is a flowchart illustrating another method for interconnecting semiconductor devices according to an embodiment of the present disclosure.

FIG. 9 is a schematic diagram of a process in the method for interconnecting the semiconductor devices shown in FIG. 1.

### DETAILED DESCRIPTION OF THE EMBODIMENTS

In order that the above objects, features and advantages of the present disclosure may be more clearly understood, a further description of various embodiments is provided below. It should be noted that, without conflict, the embodiments of the present disclosure and features in the embodiments may be combined with each other.

In the following description, numerous specific details are set forth to provide a thorough understanding of the present disclosure, but the present disclosure may be practiced otherwise than as described herein; it will be apparent that the embodiments in the specification are only some, but not all, embodiments of the disclosure.

In view of the problems set forth in the background section, embodiments of the present disclosure provide a method of interconnecting semiconductor devices and an assembly of interconnected semiconductor devices. In some embodiments, the method of interconnecting semiconductor devices includes: forming a metal layer on a first connection surface of a first semiconductor device; and forming an oxidant layer on a second connection surface of a second semiconductor device. The first connection surface has first coupling pads and the second connection surface has second coupling pads. The method further comprises aligning the first coupling pads with respective ones of the second coupling pads, whereby the first coupling pads respectively and at least partially overlap with the second coupling pads; and reacting the metal layer with the oxidant layer under the target condition to form a bonding layer between the first semiconductor device and the second semiconductor device. The bonding layer includes conductive regions and non-conductive adhesive regions. The conductive regions include first regions, second regions and third regions. Each of the first regions overlaps with a first coupling pad and a corresponding second coupling pad, each of the second region overlaps with a first coupling pad but not with any of the second coupling pads, and each of the third regions overlaps with a second coupling pad but not with any of the first coupling pads. The non-conductive adhesive regions correspond to areas not overlapping with any of the first coupling pads and the second coupling pads.

Thus, in case of misalignment (or imprecise alignment) between the first coupling pads and the corresponding second coupling pads, the second and third regions increase the effective conductive area between the first coupling pads and the corresponding second coupling pads, thereby reducing the probability of disconnection between the two coupling pads and thus improving the reliability of the interconnection. Meanwhile, the non-conductive adhesive regions provide reliable bonding areas for the first connection surface and the second connection surface, so that the bonding effect is enhanced, reliable bonding of the first connection surface and the second connection surface is realized, and interconnection reliability between the semiconductor devices is further improved. Thus, when the method of interconnecting semiconductor devices according to some embodiments is used for mass production, a certain alignment error can be allowed between two interconnected semiconductor devices, so that fault tolerance is improved, circuit breaking failure is reduced, yield is enhanced, and cost is reduced.

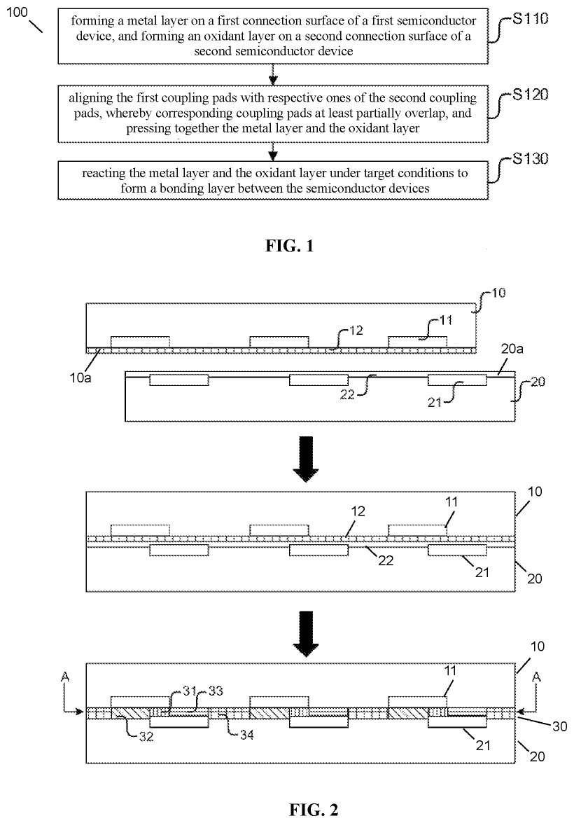

A method of interconnecting semiconductor devices and an assembly of interconnected semiconductor devices according to some embodiments of the present disclosure are described below with reference to FIGS. 1 to 9.

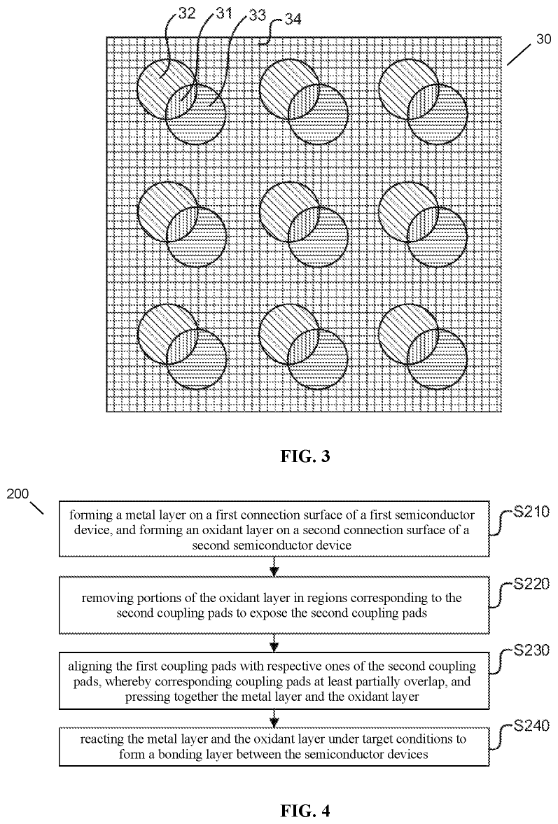

FIG. 1 is a schematic flow chart of a method 100 of interconnecting semiconductor devices according to an embodiment of the disclosure, FIG. 2 is a schematic structural diagram showing interconnected semiconductor devices at various steps in the method 100 shown in FIG. 1, and FIG. 3 is a cross-sectional view of A-A in FIG. 2. Referring to FIGS. 1 to 3, the method 100 of interconnecting semiconductor devices includes S110—forming a metal layer 12 on a first connection surface 10a of a first semiconductor device 10 and forming an oxidant layer 22 on a second connection surface 20a of a second semiconductor device 20.

The semiconductor device 10 or 20 is or includes, but is not limited to, a wafer and a chip or die, and an interconnection formed by the method 100 may be a wafer-to-wafer interconnection, a chip-to-chip (or die-to-die) interconnection, or a wafer-to-chip (or die-to-wafer) interconnection, and so on.

Referring to FIG. 2, the first semiconductor device 10 includes first coupling pads 11 exposed at the first connection surface 10a. In some embodiments, each first coupling pad 11 is a metal coupling pad and is conductive. In some embodiments, forming a metal layer 12 on the first connection surface 10a of the first semiconductor device 10 includes a vacuum sputtering or vacuum vapor deposition process. The metal layer 12 thus formed covers the first connection surface 10a including the first coupling pads 11 arranged on the first connection surface. The metal layer 12 may include at least one of aluminum, copper, zinc, iron, and silver.

The second semiconductor device 20 includes second coupling pads 21 exposed at the second connection surface 20a. In some embodiments, each second coupling pad 21 is a metal coupling pad and is conductive. In some embodiments, forming an oxidant layer 22 on the second connection surface 20a of the second semiconductor device 20 includes one or more deposition processes. The oxidant layer 22 thus formed covers the second connection surface 20a including the second coupling pads 21 at the second connection surface. The deposition processes include, but are not limited to, one or more Physical Vapor Deposition (PVD) and/or Chemical Vapor Deposition (CVD) processes, such as vacuum sputter deposition, vacuum vapor deposition, atmospheric pressure chemical vapor deposition (Atmospheric Pressure CVD or APCVD), low Pressure Chemical Vapor Deposition (LPCVD), Ultra High Vacuum Chemical Vapor Deposition (UHVCVD), and/or the like. Oxidant layer 22 thus formed is highly oxidizing and includes materials selected from, but not limited to, hydrogen peroxide, potassium permanganate, potassium perchlorate, iodine, and bromine.

In some embodiments, the method 100 of interconnecting semiconductor devices further includes S120—aligning the first coupling pads with respective ones of the second coupling pads, and pressing together the metal layer and the oxidant layer.

In some embodiments, referring to FIG. 2, the metal layer 12 on the first semiconductor device 10 and the oxidant layer 22 on the second semiconductor device 20 are brought to face each other, the first coupling pad 11 and the second coupling pad 21 are aligned with each other, and then the metal layer 12 and the oxidant layer 22 are pressed and fixed together. An alignment error is allowed between the first coupling pads 11 and the second coupling pads 21, i.e. a first coupling pad 11 and a corresponding second coupling pad 21 may be offset from each other, as long as the first coupling pads 11 at least partially overlap with the corresponding second coupling pads 21. In some embodiments, the first coupling pads 11 correspond one to one with the second coupling pads 21.

It is to be understood that the present embodiment is not limited to how the first coupling pads 11 and the second coupling pads 21 are aligned. Methods known to those skilled in the art may be adopted.

In some embodiments, the method 100 of interconnecting semiconductor devices further includes S130—reacting the metal layer and the oxidant layer under target conditions to form a bonding layer.

In some embodiments, the target conditions include conditions related to at least one of pressurizing, heating, and providing a target gas. The metal layer 12 and the oxidant layer 22 react to form a bonding layer 30 under the target conditions. As shown in FIGS. 2 and 3, the bonding layer 30 includes conductive regions and non-conductive adhesive regions. The conductive regions include first regions 31, second regions 32 and third regions 33, in the case that the first and second coupling pads are not perfectly aligned. As shown in FIGS. 2 and 3, a respective first region 31 corresponds to an area where a respective first coupling pad 11 and a corresponding second coupling pad 12 overlap. Thus, the respective first region 31 overlaps with both the respective first coupling pad 11 and the corresponding second coupling pad 12. As shown in FIGS. 2 and 3, a respective second region 32 corresponds to an area of the respective first bonding pad that does not overlap with the corresponding second coupling pad. Thus, the respective second region 32 overlaps with the respective first coupling pad but not with the corresponding second coupling pad or any other second coupling pad. As shown in FIGS. 2 and 3, a respective third region 33 corresponds to an area of a respective second bonding pad that does not overlap with a corresponding first coupling pad. Thus, the respective third region 33 overlaps with the respective second coupling pad but not with the corresponding first coupling pad or any other first coupling pad. As shown in FIGS. 2 and 3, the non-conductive adhesive regions 34 correspond to areas of the first semiconductor device and the second semiconductor device not occupied by any of the first coupling pads and the second coupling pads and thus do not overlap with any of the first coupling pads and the second coupling pads.

In some embodiments, the metal layer 12 and the oxidant layer 22 react chemically to generate metal compounds, and different metal compounds having different conductivities are formed in different areas of the bonding layer. In some embodiments, a fully conductive metal compound is formed in the first regions 31 where the first coupling pads 11 and the corresponding second coupling pads 21 overlap, because the metal (e.g., copper) in the relatively much thicker coupling pads would react with and consume the thin oxidant layer in those area. So, the first regions 31 is fully conductive to conduct electricity in the interconnection direction and in any direction perpendicular to the interconnection direction. A partially conductive metal compound is formed in the second regions 32 overlapping with the first coupling pads 11 but not with any of the second bonding pads. The side of a second region 32 facing a first coupling pad 11 is conductive because the metal in the thick coupling pad could react with the oxidant and consume most of the oxidant on that side. So, the metal oxide layer on that side is electrically conductive and able to conduct electricity in any direction perpendicular to the interconnection direction. The side of the second region 32 facing away from the first coupling pad 11 is non-conductive. A partially conductive metal compound is formed in the third regions 33 overlapping with the second coupling pads 21 but not the first bonding pads 11. The side of the third region 33 facing the second coupling pad 21 is conductive because the metal in the thick coupling pad could react with the oxidant and consume most of the oxidant on that side. So, the metal oxide layer on that side is electrically conductive and able to transmit electricity in any direction perpendicular to the interconnection direction. The side of the third region 33 facing away from the second coupling pad 21 is non-conductive. Thus, the effective conductive area of a coupling pad 11 on the first semiconductor device 10 and a corresponding coupling pad 21 on the second semiconductor device 20 is the sum of the corresponding first region 31, second region 32, and third region 33. Compared with the related art, in the case that the first coupling pad 11 and the second coupling pad 21 are offset (not precisely aligned), the method for interconnecting the semiconductor devices increases the effective conductive area between the first semiconductor device 10 and the second semiconductor device 20, and the first semiconductor device 10 and the second semiconductor device 20 can be electrically interconnected not only through the first regions 31 overlapping with the first coupling pads 11 and the second coupling pads 21, but also through the increased conductive regions (the second regions 32 overlapping with only the first coupling pads 11 and the third regions 33 overlapping with only the second coupling pads 12), thereby reducing the probability of disconnection between the coupling pads and improving the interconnection reliability of the semiconductor devices.

Referring to FIGS. 2 and 3, a non-conductive adhesive compound is formed in the fourth region 34 in the bonding layer, a region not occupied by any of the first coupling pads 11 and the second coupling pads 21 (or a region not overlapping with any of the first coupling pads and second coupling pads). In the fourth regions 34, the metal(s) in the metal layer 12 has fully reacted with the oxidant in the oxidant layer 22 in a chemical reaction, which generates a metal compound that is dense and stable, and that provides a reliable bond between the first connection surface and the second connection surface in the fourth region. As a result, the bonding of the first connection surface and the second connection surface is enhanced, thereby realizing reliable bonding of the first semiconductor device 10 and the second semiconductor device 20, and further increasing the interconnection reliability of the semiconductor devices.

Thus, a method of interconnecting semiconductor devices according to some embodiments comprises: forming a metal layer on a first connection surface of the first semiconductor device and forming an oxidant layer on the second connection surface of the second semiconductor device; wherein the first connection surface comprises the first coupling pad and the second connection surface comprises the second coupling pad; aligning the first coupling pads and the second coupling pads with each other, and pressing together the metal layer and the oxidant layer, the first coupling pad and the second coupling pad at least partially overlapping in one-to-one correspondence; reacting the metal layer with the oxidant layer under target condition to form a bonding layer. The bonding layer has conductive regions including first, second and third regions: each of the first regions corresponding to an area where a first coupling pad overlaps with a corresponding second coupling pad, each of the second region corresponding to a part of a first coupling pad not overlapping with a corresponding second coupling pad, each of the third regions corresponding to a part of a second coupling pad not overlapping with a corresponding first coupling pad. Thus, in the case of misalignment (or imprecise alignment) between a first coupling pads and a second coupling pad, the effective conductive area between the first coupling pad and the second coupling pad is increased, thereby reducing the probability of disconnection between the two coupling pads and thus improving the reliability of the interconnection. Meanwhile, the bonding layer further includes a fourth region providing a reliable bonding area for the first connection surface and the second connection surface, so that the bonding effect is enhanced, the reliable bonding of the first connection surface and the second connection surface is realized, and the interconnection reliability between the semiconductor devices is further enhanced. When the method of interconnecting semiconductor devices is used for mass production, a certain alignment error can be allowed between two interconnected semiconductor devices, so that fault tolerance is improved, circuit breaking failure is reduced, yield is improved, and the cost is reduced.

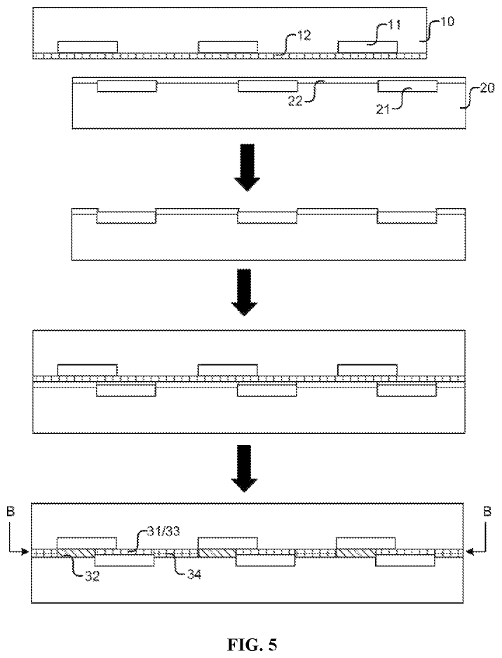

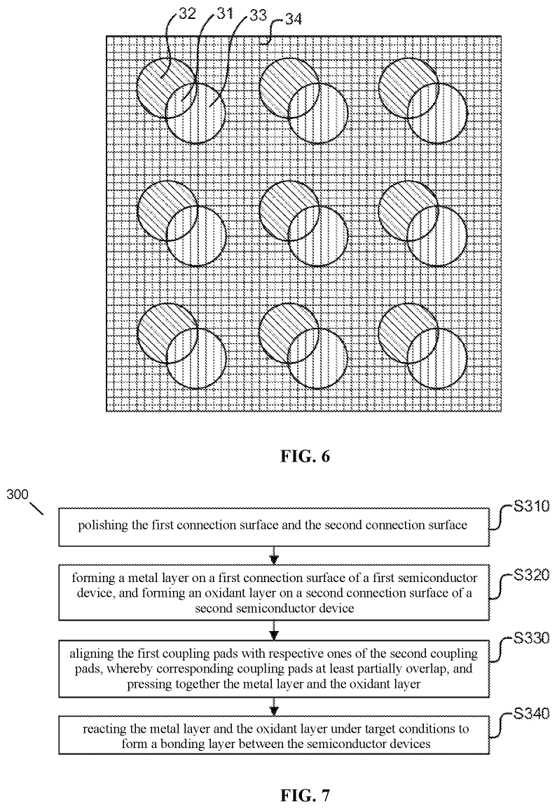

FIGS. 4-6 illustrate a method 200 of interconnecting semiconductor devices according to some embodiments. FIG. 4 is a schematic flow chart illustrating method 200 for interconnecting semiconductor devices, FIG. 5 is a schematic structural diagram corresponding to various steps in the method 200 for interconnecting semiconductor devices shown in FIG. 4, and FIG. 6 is a cross-sectional view of B-B in FIG. 5. Referring to FIGS. 4-6, method 200 includes S210, S230 and S240, which are similar to S110, S120 and S130, respectively, in method 100. Method 200 further includes S220—removing portions of the oxidant layer 22 in the areas corresponding to the second coupling pads 21 to expose the second coupling pads 21, prior to S230—aligning the first coupling pad and the second coupling pad with each other and pressing together the metal layer and the oxidant layer.

In some embodiments, an etching process is adopted to remove the oxidant layer 22 in the areas corresponding to the second coupling pads 21, so that the second coupling pads 21 previously covered by the oxidant layer 22 are exposed on the surface of the oxidant layer 22. In the interconnection direction (i.e., the direction perpendicular to the second connection surface 20a, the exposed surfaces of the second coupling pads 21 is lower than the surface of the oxidant layer 22 (i.e., the exposed surfaces of the second coupling pads 21 is recessed from the surface of the oxidant layer 22). Thus, grooves are formed above the second coupling pads 21. Since portions of the oxidant layer 22 above the second coupling pads 21 are removed, the metal layer 12 in the areas corresponding to the second coupling pads 21 do not undergo chemical reaction when the subsequent steps are performed, and after the pressurization, heating and annealing treatment, the metal layer 12 in these areas undergoes thermal expansion to generate extrusion into the grooves to realize interface contact with the second coupling pads; in this way, the first regions 31 in the bonding layer 30 overlapping with the first coupling pad 11 and the second coupling pad 21, and the third regions 33 overlapping with the second coupling pads 12 but not with the first coupling pads, are all metal layers, and are fully conductive. As a result, the probability of disconnection between the two coupling pads is further reduced, and the interconnection reliability of the semiconductor device is improved.

It should be noted that since S210, S230 and S240 are similar to S110, S120 and S130, respectively, reference is made to the explanation of S110 to S130, and the description of S210, S230 and S240 are not repeated here.

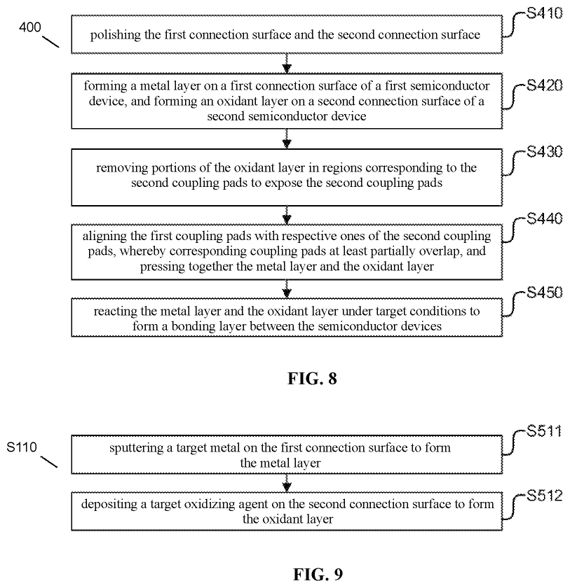

FIG. 7 and FIG. 8 show flowcharts of additional methods 300 and 400 for interconnecting semiconductor devices according to embodiments. As shown in FIG. 7/FIG. 8, the method 300/400 of interconnecting semiconductor devices includes S320/S420, in which a metal layer is formed on the first connection surface of the first semiconductor device and an oxidant layer is formed on the second connection surface of the second semiconductor device, and before S320/S420, the method 300/400 further includes: S310/S410—performing polishing or planarization treatment on the first connection surface 10 and the second connection surface 20.

In some embodiments, a grinding or polishing process may be used to polish/grind/planarize the first and second connection surfaces to achieve uniform planarization of the first and second connection surfaces 10a and 20a. For example, known Chemical Mechanical Polishing (CMP) technologies can be used to achieve efficient removal of excess material on the semiconductor device junctions, and also global nanoscale planarization by a synergistic combination of chemical etching and mechanical polishing.

In one embodiment, the first semiconductor device 10 is a wafer or a die, and the second semiconductor device 20 is a wafer or a die (or chip).

The interconnection between the first semiconductor device and the second semiconductor device may be, but is not limited to, wafer-to-wafer interconnection, chip-to-chip interconnection, or wafer-to-chip interconnection.

FIG. 9 is a flowchart of S110 in the method 100 for interconnecting the semiconductor devices shown in FIG. 1 according to embodiments. Referring to FIG. 9, forming a metal layer at a first connection surface of a first semiconductor device in S110 includes: S511—sputtering a target metal on the first connection surface to form a metal layer.

In some embodiments, a metal layer is formed on the first connection surface 10a by adopting a vacuum sputter deposition technology, and the formed metal layer has the advantages of uniform and controllable thickness, difficult to fall off, etc. The thickness of the metal layer is controlled to be nanoscale or micro-scale.

In other embodiments, the metal layer may be formed by a vacuum evaporation deposition process, or by other processes known to those skilled in the art, which are not limited herein.

In one embodiment, the target metal comprises at least one of aluminum, copper, zinc, tin, nickel, iron, and silver. In other embodiments, the target metal may be other metals known to those skilled in the art, which are not limited herein. In some embodiments, the target metal has strong metal activity and is easy to oxidize.

In some embodiments, the metal layer may a single metal film layer, or may include a plurality of stacked metal film layers.

In one embodiment, as shown in FIG. 9, forming an oxidant layer at the second connection surface of the second semiconductor device in S110 includes S512—depositing a target oxidizing agent or oxidant on the second connection surface to form an oxidant layer.

In some embodiments, an oxidant layer is formed on the second connection surface using a deposition process including, but not limited to, physical vapor deposition and chemical vapor deposition, such as vacuum sputter deposition, vacuum evaporation deposition, atmospheric pressure chemical vapor deposition, low pressure chemical vapor deposition, ultra-high vacuum chemical vapor deposition, and the like.

The order of executing S511 and S512 in S110 is not limited, i.e., S511 may be performed before S512, after S512, or concurrently with S512.

In one embodiment, the target oxidizing agent or oxidant comprises at least one of hydrogen peroxide, potassium permanganate, potassium perchlorate, iodine, and bromine.

In some embodiments, the target oxidizing agent is capable of chemically reacting with the target metal to form a metal compound, and the solid metal compound is non-conductive because the metal ions are immobilized.

In other embodiments, the target oxidizing agent may be other oxidizing agents known to those skilled in the art, and is not limited herein.

In one embodiment, the target conditions include conditions related to at least one of pressurizing, heating, and providing a target gas.

Target conditions are used provide controllability of the reaction speed of the metal layer and the oxidation layer, and if the reaction speed of the target metal and the target oxidant is slow or the target metal and the target oxidant do not react at normal temperature and normal pressure, the reaction speed of the target metal and the target oxidant is accelerated by providing the target conditions for the metal layer and the oxidation layer, so that the metal layer is more rapidly oxidized. On the other hand, if the reaction between the target metal and the target oxidant is severe and fast, the target condition is provided for the metal layer and the oxidant layer to inhibit the reaction between the target metal and the target oxidant, so that the reaction speed of the target metal and the target oxidant is slowed down, and the metal layer is prevented from being excessively oxidized. The pressure, temperature and the type and concentration of the target gas in the target conditions are determined according to the types of the target metal and the target oxidant. For different types of metal and oxidant, the corresponding target conditions can be different.

It should be noted that, in addition to the reaction speed of the target metal and the target oxidizing agent, the reaction time between the metal layer and the oxidant layer is affected, and the thickness of the metal layer and the thickness of the oxidant layer are also important factors that affect the reaction time. Illustratively, the metal layer has a thickness of tens of nanometers or micrometers.

In one embodiment, the target gas includes one of oxygen, chlorine, and fluorine.

Oxygen, chlorine and fluorine have strong oxidizing property, and can accelerate the reaction speed of the target metal and the target oxidant.

In other embodiments, the target gas may also be nitrogen or an inert gas, which helps with removing oxygen between the metal layer and the oxidant layer to slow down the reaction rate of the target metal and the target oxidant.

Based on the foregoing embodiments, embodiments of the present disclosure further provide an assembly of interconnected semiconductor devices, where the interconnection of the semiconductor devices is formed using the method of interconnecting semiconductor devices according to some embodiments, and has corresponding beneficial effects, which are not repeated here.

As shown in FIGS. 2 to 3 or FIGS. 5 to 6, the interconnected semiconductor device comprises: a first semiconductor device 10 including the first coupling pads 11; a second semiconductor device 20 including the second coupling pads 21; the second coupling pads 21 at least partially overlapping with respective ones of the first coupling pads 11 and are interconnected in a one-to-one correspondence with the first coupling pads; and a bonding layer 30 between the first semiconductor device 10 and the second semiconductor device 20. The bonding layer 30 includes conductive regions 31, 32, 33 and non-conductive adhesive regions 34. The conductive regions include first regions 31, second regions 32 and third regions 33. A respective first region 31 corresponds to an area where a respective first coupling pad 11 and a corresponding second coupling pad 12 overlap (i.e., the respective first region 31 overlaps with both respective first coupling pad 11 and the corresponding second coupling pad 12). A respective second region 32 corresponds to and overlaps with an area of the respective first bonding pad that does not overlap with the corresponding second coupling pad (i.e., the respective second region 32 overlaps with the respective first coupling pad but not with the corresponding second coupling pad or any other second coupling pad). A respective third region 33 corresponds to and overlaps with an area of a respective second bonding pad that does not overlap with a corresponding first coupling pad (i.e., the respective third region 33 overlaps with the respective second coupling pad but not with the corresponding first coupling pad or any other first coupling pad). The non-conductive adhesive regions correspond to areas not occupied by any of the first coupling pads and the second coupling pads and thus do not overlap with any of the first coupling pads and the second coupling pads.

In some embodiments, the first regions 31 is occupied by a fully conductive metal compound, so the first regions 31 have conductivity to conduct electricity in the interconnection direction and in any direction perpendicular to the interconnection direction. The second regions 32 includes a partly conductive metal compound and/or a combination of metal and metal compound. The side of a second region 32 facing a first coupling pad 11 is conductive and able to conduct electricity in any direction perpendicular to the interconnection direction. The side of the second region 32 facing away from the first coupling pad 11 is non-conductive. The third regions 33 also includes a partly conductive metal compound and/or a combination of metal and metal compound. The side of the third region 33 facing the second coupling pad 21 is conductive, able to transmit electricity in any direction perpendicular to the interconnection direction, while the side of the third region 33 facing away from the second coupling pad 21 is non-conductive. Thus, the effective conductive area of the first semiconductor device 10 and the second semiconductor device 20 is the sum of the first region 31, the second region 32, and the third region 33. Compared with the related art, in the case that the first coupling pad 11 and the second coupling pad 21 are offset (not precisely aligned), the interconnection between the semiconductor devices increases the effective conductive area between the first semiconductor device 10 and the second semiconductor device 20, and the first semiconductor device 10 and the second semiconductor device 20 can be electrically interconnected not only through the first regions 31 overlapping with the first coupling pad 11 and the second coupling pad 21, but also through the increased conductive regions (the second regions 32 overlapping with only the first coupling pads 11 and the third regions 33 overlapping with only the second coupling pads 12), thereby reducing the probability of occurrence of disconnection between the two coupling pads, thereby improving the interconnection reliability of the semiconductor devices.

The fourth region 34 is an adhesion region bonding the first semiconductor device 10 to the second semiconductor device 20, and includes a metal compound formed by complete chemically reaction between the metal layer 12 and the chemical layer 22 in the corresponding region. The fourth region 34 is non-conductive and stable, enabling reliable bonding of the first semiconductor device 10 and the second semiconductor device 20, further increasing the interconnect reliability of the semiconductor devices.

In one embodiment, the bonding layer includes, but is not limited to, aluminum oxide, copper oxide, tin oxide, iron oxide, zinc oxide, silver oxide, aluminum chloride, copper chloride, iron chloride, zinc chloride, silver chloride, aluminum iodide, copper iodide, and/or silver iodide.

It should be noted that in this document, relational terms such as “first” and “second” and the like are used solely to distinguish one entity or action from another entity or action without necessarily requiring or implying any actual such relationship or order between such entities or actions. Moreover, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Without further limitation, an element defined by the phrase “comprising one . . . ” does not exclude the presence of other like elements in a process, method, article, or apparatus that comprises the element.

The foregoing is merely a specific embodiment of the disclosure to enable one skilled in the art to understand or practice the disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown and described herein but is to be accorded the widest scope consistent with the principles and novel features disclosed herein.

1. A method of interconnecting semiconductor devices, comprising:
forming a metal layer on a first connection surface of a first semiconductor device, the first connection surface having first coupling pads;
forming an oxidant layer on a second connection surface of a second semiconductor device, the second connection surface having second coupling pads;
aligning the first coupling pads with respective ones of the second coupling pads, whereby the first coupling pads at least partially overlap with respective ones of the second coupling pads;
pressing together the metal layer and the oxidant layer;
reacting the metal layer and the oxidant layer under target conditions to form a bonding layer between the first semiconductor device and the second semiconductor device, the bonding layer including conductive regions and non-conductive adhesive regions, the conductive regions including first regions, second regions and third regions, each of the first regions overlapping with a first coupling pad and a corresponding second coupling pad, each of the second region overlapping with a first coupling pad but not with any of the second coupling pads, each of the third regions overlapping with a second coupling pad but not with any of the first coupling pads, and the non-conductive adhesive regions corresponding to areas not overlapping with any of the first coupling pads and the second coupling pads.

2. The method of claim 1, further comprising, prior to aligning the first coupling pads with respective ones of the second coupling pads and pressing together the metal layer and the oxidant layer, the method further comprises:
removing portions of the oxidant layer in regions corresponding to the second coupling pads to expose the second coupling pads.

3. The method of claim 1, further comprising:
polishing the first connection surface before forming the metal layer thereon; and/or
polishing the second connection surface before forming the oxidant layer thereon.

4. The method of claim 1 wherein at least one of the first semiconductor device and the second semiconductor device is on a respective wafer or a respective die.

5. The method of any of claims 1, wherein forming a metal layer on the first connection surface of the first semiconductor device comprises:
sputtering a target metal on the first connection surface to form the metal layer.

6. The method of claim 5 wherein said target metal comprises at least one of aluminum, copper, zinc, tin, nickel, iron, and silver.

7. The method of any of claims 1, wherein forming an oxidant layer on the second connection surface of the second semiconductor device comprises:
depositing a target oxidizing agent on the second connection surface to form the oxidant layer.

8. The method of claim 7 wherein said target oxidizing agent comprises at least one of hydrogen peroxide, potassium permanganate, potassium perchlorate, iodine and bromine.

9. The method of claim 1, wherein the target conditions include conditions related to at least one of pressurizing, heating, and providing a target gas.

10. The method of claim 9 wherein said target gas comprises one of oxygen, chlorine and fluorine.

11. A semiconductor device assembly, comprising:
a first semiconductor device including first coupling pads;
a second semiconductor device including second coupling pads, wherein the first coupling pads at least partially overlap with, and are connected to, respective ones of the second coupling pads; and
a bonding layer between the first semiconductor device and the second semiconductor device, the bonding layer including conductive regions and non-conductive adhesive regions, the conductive regions including first regions, second regions and third regions, each of the first regions overlapping with a first coupling pad and a corresponding second coupling pad, each of the second region overlapping with a first coupling pad but not with any of the second coupling pads, each of the third regions overlapping with a second coupling pad but not with any of the first coupling pads, and the non-conductive adhesive regions corresponding to areas not overlapping with any of the first coupling pads and the second coupling pads.
